(19) United States
(12) Patent Application Publication
(10) Pub. No.: US 2026/0016541 A1
(43) Pub. Date: Jan. 15, 2026

(54) APPARATUS AND METHOD FOR DIAGNOSING BATTERY

(71) Applicants: HYUNDAI MOTOR COMPANY, Seoul (KR); KIA CORPORATION, Seoul (KR); Research & Business Foundation SUNGKYUNKWAN UNIVERSITY, Suwon-si (KR)

(72) Inventors: Joonkeun YOON, Hwaseong-si (KR); Seung-Beom YOON, Hwaseong-si (KR); Won-Sub YOON, Seoul (KR); Sang-Bin PARK, Suwon-si (KR); Sung-Bum LEE, Suwon-si (KR)

(73) Assignees: HYUNDAI MOTOR COMPANY, Seoul (KR); KIA CORPORATION, Seoul (KR); Research & Business Foundation SUNGKYUNKWAN UNIVERSITY, Suwon-si (KR)

(21) Appl. No.: 18/960,262

(22) Filed: Nov. 26, 2024

(30) Foreign Application Priority Data
Jul. 15, 2024 (KR) 10-2024-0092760

(51) Int. Cl. G01R 31/382; H02J 7/00

(52) U.S. Cl. CPC G01R 31/382; H02J 7/0048; H02J 7/00712

(57) ABSTRACT

A battery diagnosing apparatus includes a charged-state detector configured to detect a charged state of a battery, a charging current controller configured to vary a charging current for the battery when the charged state of the battery corresponds to a predetermined diagnosis charging range, and a battery diagnosing unit configured to analyze a charging profile generated during charging of the battery, thereby determining whether or not the battery is abnormal.

### CROSS-REFERENCE TO RELATED PATENT APPLICATION

This application claims priority to Korean Patent Application No. 10-2024-0092760, filed Jul. 15, 2024, whose entire disclosures are hereby incorporated by reference.

### FIELD

The present disclosure relates to an apparatus and method for diagnosing a battery, and more particularly to a battery diagnosing apparatus and method for analyzing a charging profile of a battery, thereby determining whether the battery is abnormal.

### BACKGROUND

Generally, a battery used in an electric vehicle or the like is constituted by a large number of battery cells having the same standard. Such battery cells are combined or modularized to manufacture a battery having a desired standard and desired performance (for example, voltage, capacity, etc.) (Such a battery and such battery cells will be collectively referred to as a battery hereinafter without being distinguished from each other).

Meanwhile, in such a battery, over-charging, over-discharging, overcurrent, etc. may be generated as use of the battery is continued, because performance of materials constituting the battery is varied or degraded. In order to maintain the battery in an optimum state while preventing generation of such over-charging, over-discharging, overcurrent, etc., diagnosis (evaluation) and management of the battery is needed.

In connection with this, in conventional cases, determination and diagnosis of a state of the battery are performed through monitoring of a voltage of the battery or analyzing a charging profile of the battery for the entire charging range in which the battery is charged. For generation of a charging profile for diagnosis of the battery, however, charging should be performed at a charging speed (The charging speed will be referred to as a “diagnosis charging speed” hereinafter.) much lower than a general charging speed. For this reason, in such conventional cases, there are problems of low diagnosis speed and low diagnosis efficiency in that charging is performed at the diagnosis charging speed for the entire battery charging range and as such, a lot of time is taken for battery diagnosis.

### SUMMARY

Therefore, the present disclosure has been made in view of the above problems, and it is an object of the present disclosure to provide a battery diagnosing apparatus and method capable of rapidly and accurately diagnosing a battery by performing charging of the battery at a diagnosis charging speed lower than a general charging speed only for a charging range requiring precise diagnosis of the battery (referred to as a “diagnosis charging range” hereinafter) while performing charging of the battery at the general charging speed for a charging range other than the diagnosis charging range.

It is another object of the present disclosure to provide a battery diagnosing apparatus and method configured to determine whether or not a battery is abnormal by analyzing a charging profile of the battery only for a predetermined diagnosis charging range.

It is another object of the present disclosure to provide a battery diagnosing apparatus and method configured to determine whether or not a battery is safe, based on a first peak of a charging profile of the battery.

Objects of the present disclosure are not limited to the above-mentioned object, and other objects and advantages of the present disclosure, which are not mentioned, will be understood through the following description, and will become apparent from embodiments of the present disclosure. It is also to be understood that the objects and advantages of the present disclosure may be realized by means and combinations thereof set forth in claims.

In accordance with an aspect of the present disclosure, the above and other objects can be accomplished by the provision of a battery diagnosing apparatus including a charged-state detector configured to detect a charged state of a battery, a charging current controller configured to vary a charging current for the battery when the charged state of the battery corresponds to a predetermined diagnosis charging range, a charging profile generator configured to generate a charging profile for the diagnosis charging range of the battery, and a battery diagnosing unit configured to analyze the generated charging profile, thereby determining whether or not the battery is abnormal.

The diagnosis charging range may be set with reference to a first peak of an intrinsic charging profile of the battery.

The battery diagnosing unit may analyze whether or not a first peak of the generated charging profile is positioned in a predetermined safe area, thereby determining whether or not the battery is abnormal.

The safe area may be set based on an average and a standard deviation of first peaks of intrinsic charging profiles for a plurality of batteries having a standard identical to a standard of the battery.

The charging profile may be incremental capacity & differential voltage (IC-DV) information as to the battery.

In another aspect of the disclosure, there is provided a battery diagnosing method including detecting a charged state of a battery, varying a charging current for the battery when the charged state of the battery corresponds to a predetermined diagnosis charging range, thereby generating a charging profile for the diagnosis charging range of the battery, and analyzing the generated charging profile, thereby determining whether or not the battery is abnormal.

The determining whether or not the battery is abnormal may include analyzing whether or not a first peak of the generated charging profile is positioned in a predetermined safe area.

### BRIEF DESCRIPTION OF THE DRAWINGS

The above and other objects, features and other advantages of the present disclosure will be more clearly understood from the following detailed description taken in conjunction with the accompanying drawings, in which:

FIGS. 1A, 1B, and 1C are graphs depicting a charging profile when charging of a battery is performed at a diagnosis charging speed for the entire battery charging range;

FIGS. 2A, 2B, and 2C are graphs depicting a charging profile in the case in which the battery is charged at the diagnosis charging speed only for a portion of the entire battery charging range;

FIGS. 3A and 3B are graphs depicting influence of a cathode and an anode of a battery on a charging profile;

FIG. 4 is a configuration diagram of a battery diagnosing apparatus according to an embodiment of the present disclosure;

FIG. 5 is a flowchart of a battery diagnosing method according to an embodiment of the present disclosure;

FIG. 6 is a graph explaining a battery charging current control system according to an embodiment of the present disclosure;

FIG. 7 is a graph explaining a safe area setting method according to an embodiment of the present disclosure; and

FIG. 8 is a graph explaining a battery diagnosing method according to an embodiment of the present disclosure.

### DETAILED DESCRIPTION

Hereinafter, reference will be made in detail to exemplary embodiments of the present disclosure, examples of which are illustrated in the accompanying drawings and described below, and wherever possible, the same or similar elements will be denoted by the same reference numerals even though they are depicted in different drawings and a redundant description thereof will thus be omitted. In the following description of the embodiments, suffixes, such as “module”, and “part”, are provided or used interchangeably merely in consideration of ease in statement of the specification, and do not have meanings or functions distinguished from one another. In the following description of the embodiments of the present disclosure, a detailed description of known functions and configurations incorporated herein will be omitted when it may make the subject matter of the present disclosure rather unclear. Further, the accompanying drawings will be exemplarily given to describe the embodiments of the present disclosure, and should not be construed as being limited to the embodiments set forth herein, and it will be understood that the embodiments of the present disclosure are provided only to completely disclose the disclosure and cover modifications, equivalents or alternatives which come within the scope and technical range of the disclosure.

In the following description of the embodiments, terms, such as “first” and “second”, are used only to describe various elements, and these elements should not be construed as being limited by these terms. These terms are used only to distinguish one element from other elements.

When an element or layer is referred to as being “connected to” or “coupled to” another element or layer, it may be directly connected or coupled to the other element or layer, or intervening elements or layers may be present. In contrast, when an element or layer is referred to as being “directly connected to” or “directly coupled to” another element or layer, there may be no intervening elements or layers present.

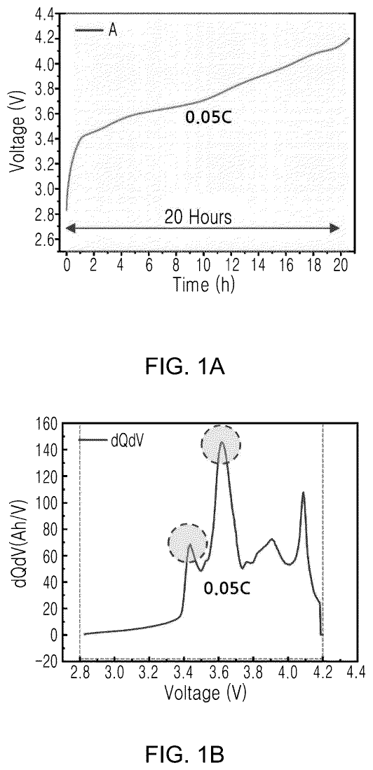

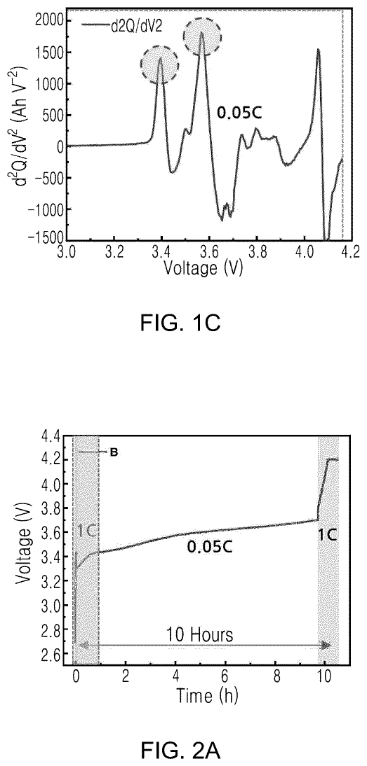

Hereinafter, a battery diagnosing apparatus and method according to the present disclosure will be described with reference to FIGS. 1 to 8.

Typically, charging of a battery is performed at a general charging speed of 1C (C-rate) or more (For reference, “1C” means a charging speed at which 1 hour is taken to fully charge the battery.).

However, when battery diagnosis is performed, battery charging is performed at a charging speed (a diagnosis charging speed) much lower than the general charging speed, for example, a charging speed of 0.1C or less, for accurate evaluation of a battery state (For reference, “0.1C” means a charging speed at which 10 hours are taken to fully charge the battery.), and a charging profile for the battery is generate during charging of the battery, and is analyzed to diagnose a state of the battery.

In connection with this, FIGS. 1A-1C are graphs depicting a charging profile when charging of a battery is performed at a diagnosis charging speed for the entire battery charging range. FIGS. 1A-1C show a charging profile depicting a variation in voltage with passage of time (see FIG. 1A, a charging profile depicting variation of a first derivative dQ/dV of a charging amount with respect to a voltage (“Q” represents a charging amount of the battery, and “V” represents a voltage of the battery.) (see FIG. 1B, and a charging profile depicting variation of a second derivative d2Q/dV2 of a charging amount with respect to a voltage (see FIG. 1C) in the case in which battery charging is performed for 20 hours at a diagnosis charging speed of 0.05C for the entire battery charging range.

Referring to FIGS. 1B and 1C, it may be seen that a peak is generated several times during charging of the battery as the first derivative dQ/dV and the second derivative d2Q/dV2 are varied. In accordance with the present disclosure, positions (coordinates) of peaks of such charging profiles (for example, incremental capacity & differential voltage (IC-DV) information) are analyzed to achieve precise diagnosis of the battery.

In the present disclosure, therefore, precise diagnosis is needed only for a charging range in which a peak required for analysis (for example, a first peak) is generated and, as such, the battery is charged at a diagnosis charging speed lower than the general charging speed only for a charging range requiring precise diagnosis (that is, a diagnosis charging range), whereas the battery is charged at the general charging speed for a charging range other than the diagnosis charging range. Accordingly, it may be possible to greatly reduce the time taken for battery diagnosis.

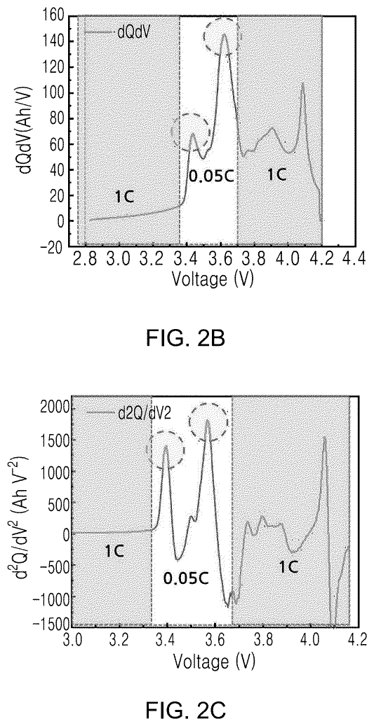

In connection with this, FIGS. 2A-2C are graphs depicting a charging profile in the case in which the battery is charged at the diagnosis charging speed only for a portion of the entire battery charging range (that is, a diagnosis charging range). FIGS. 2A-2C show a charging profile depicting a variation in voltage with passage of time (see FIG. 2A), a charging profile depicting variation of a first derivative dQ/dV of a charging amount with respect to a voltage (see FIG. 2B), and a charging profile depicting variation of a second derivative d2Q/dV2 of a charging amount with respect to a voltage (see FIG. 2C) in the case in which battery charging is first performed at a general charging speed of 1C, is then performed at a diagnosis charging speed of 0.05C in a diagnosis charging range, and is again performed at the general charging speed of 1C after completion of the diagnosis charging range.

Referring to FIGS. 2A and 2B, it may be seen that variations of the first derivative dQ/dV and the second derivative d2Q/dV2 and generation of peaks are similar to those of FIGS. 1B and 1C, but the charging time is greatly reduced to about 10 hours and, as such, it may be seen that the battery diagnosis time may be greatly reduced.

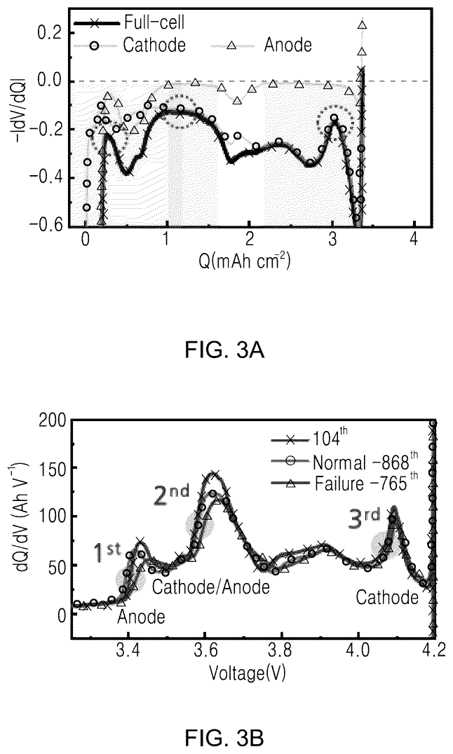

Meanwhile, FIGS. 3A-3B are graphs depicting influence of a cathode and an anode of a battery on a charging profile.

Referring to FIG. 3A, it may be seen from results of an experiment for the electrodes of the battery that a first peak of a charging profile is greatly influenced by the anode of the battery, a second peak of the charging profile is influenced by both the cathode and the anode of the battery, and a third peak of the charging profile is greatly influenced by the cathode of the battery.

In addition, referring to FIG. 3B, it may be seen that, in an abnormal (failure) state of the battery, the position of a first peak is greatly different from that in a normal state of the battery. From this, it may be determined that, when the battery is in an abnormal state, the anode of the battery is weak against a non-uniform reaction in particular. Accordingly, it may be seen that whether or not the battery is abnormal may be determined through analysis of the position of only the first peak.

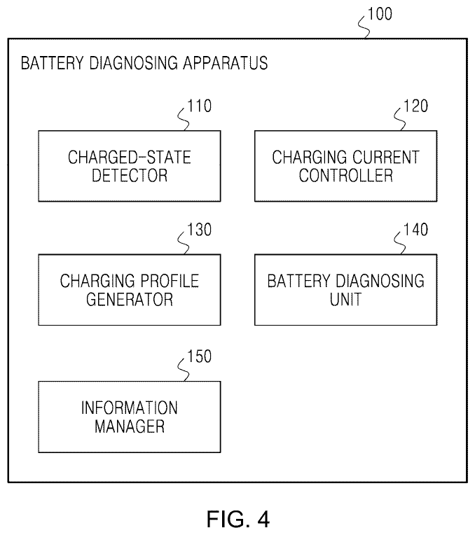

Hereinafter, a battery diagnosing apparatus and method according to embodiments of the present disclosure will be described with reference to FIGS. 4 to 8.

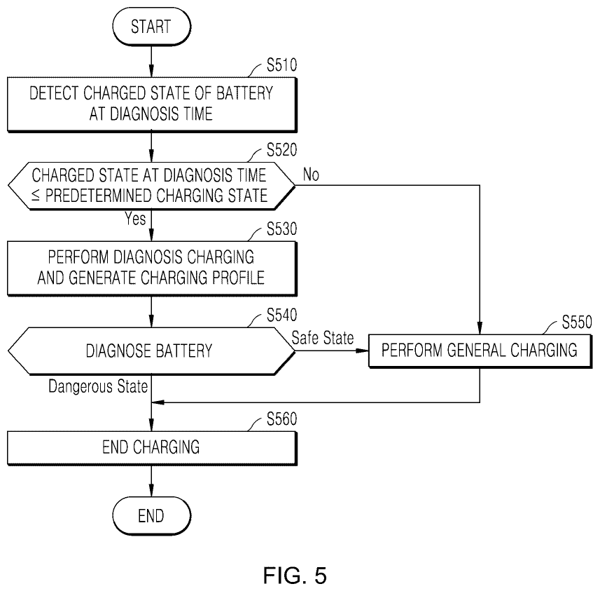

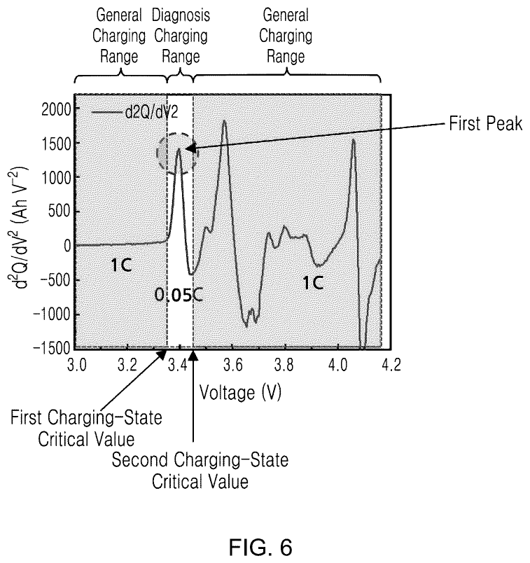

FIG. 4 is a configuration diagram of a battery diagnosing apparatus according to an embodiment of the present disclosure. FIG. 5 is a flowchart of a battery diagnosing method according to an embodiment of the present disclosure. In addition, FIG. 6 is a graph explaining a battery charging current control system according to an embodiment of the present disclosure.

Referring to FIG. 4, the battery diagnosing apparatus according to the embodiment of the present disclosure, which is designated by reference numeral “100”, includes a charged-state detector 110, a charging current controller 120, a charging profile generator 130, a battery diagnosing unit 140, an information manager 150, etc.

The charged-state detector 110 detects a charged state of a battery using a state-of-charge (SoC) measuring method according to a known technology (for example, a voltage measurement method, an open circuit voltage (OCV) measurement method, a current integration method, a chemical measurement method, or a pressure measurement method) (see step S510 in FIG. 5).

Then, the charging current controller 120 controls a charging current (charging speed) of the battery to be different in different charging ranges, respectively, based on the charged state of the battery detected by the charged-state detector 110.

For example, the charging current controller 120 checks whether or not the charged state of the battery at a battery diagnosis start time is not more than a predetermined first charging-state critical value defining start of a diagnosis charging range (see FIG. 6), thereby determining whether or not diagnosis of the battery is possible (see step S520 in FIG. 5).

When the charged state of the battery at the battery diagnosis start time is not more than the predetermined first charging-state critical value at step S520, it may be possible to accurately detect a first peak of a charging profile. In this case, accordingly, general charging is performed at a general charging speed of, for example, 1C, until the charged state of the battery reaches the predetermined first charging-state critical value (that is, until a diagnosis charging range starts). When the charged state of the battery at the battery diagnosis start time is more than the predetermined first charging-state critical value (that is, when the diagnosis charging range starts), diagnosis charging is performed at a diagnosis charging speed of, for example, 0.05C (see step S530 in FIG. 5). In addition, when the charged state of the battery is more than a predetermined second charging-state critical value defining end of the diagnosis charging range (see FIG. 6) (That is, the diagnosis charging range ends.) in a state in which there is no abnormality (failure) in battery diagnosis (see step S540 in FIG. 5), the charging current controller 120 again performs general charging at a general charging speed of, for example, 1C (see step S550 in FIG. 5).

On the other hand, when the charged state of the battery at the battery diagnosis start time is more than the predetermined first charging-state critical value at step S520, it may be impossible to accurately detect the first peak of the charging profile. In this case, accordingly, the charging current controller 120 performs general charging at a general charging speed of, for example, 1C, without performing diagnosis charging (see step S550 in FIG. 5).

Again referring to FIG. 4, the charging profile generator 130 generates a charging profile (for example, a charging profile representing variation of a first derivative dQ/dV of a charging amount with respect to a voltage and a charging profile depicting variation of a second derivative d2Q/dV2 of a charging amount with respect to a voltage) for the charging range in which the battery is charged, preferably, the diagnosis charging range (see step S530 in FIG. 5).

In accordance with a preferred embodiment of the present disclosure, when diagnosis of a battery is performed for the first time, charging of the battery is performed at a diagnosis charging speed for the entire battery charging range, thereby generating and storing an intrinsic charging profile for the entire battery charging range. In addition, a position (coordinates), at which a first peak of the intrinsic charging profile is generated, is identified, and a diagnosis charging range is set through reflection of a predetermined voltage deviation with reference to the first peak position. For example, in the case of FIG. 6, a diagnosis charging range from 3.35V (a first charging-state critical value) to 3.45V (a second charging-state critical value) is set through reflection of a voltage deviation of 0.05V with reference to a first peak position of 3.4V.

As such, when the battery is subsequently diagnosed under the above-described setting condition, charging is performed at a diagnosis charging speed lower than a general charging speed only for the diagnosis charging range, thereby generating a charging profile, and charging is rapidly performed at a general charging speed for a charging range other than the diagnosis charging range.

Meanwhile, the battery diagnosing unit 140 analyzes the charging profile generated by the charging profile generator 130, thereby determining whether or not the battery is abnormal.

For example, the battery diagnosing unit 140 determines whether or not the first peak position (coordinates) of the charging profile is present in a predetermined safe area, thereby determining whether the battery is in a safe state or a dangerous state.

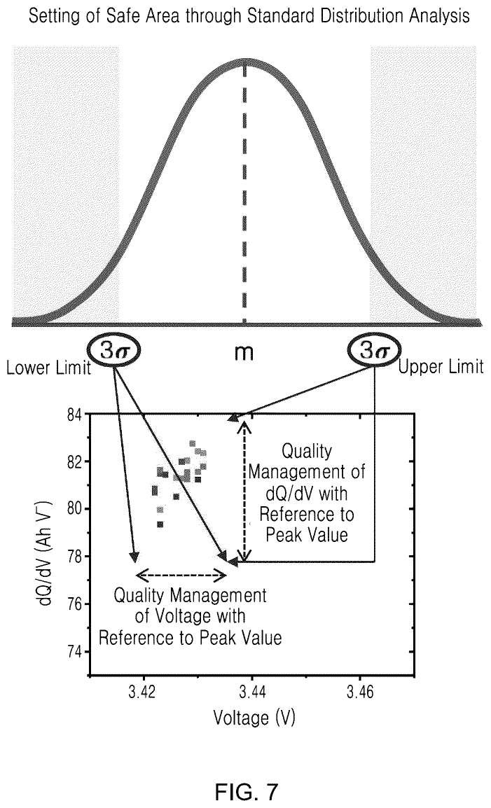

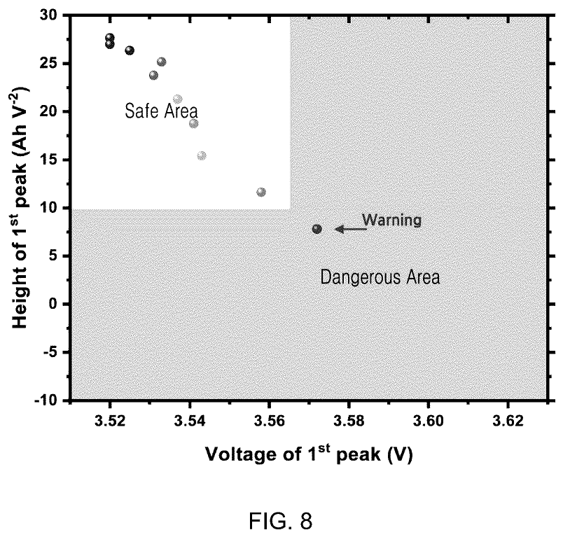

In connection with this, FIG. 7 is a graph explaining a safe area setting method according to an embodiment of the present disclosure, and FIG. 8 is a graph explaining a battery diagnosing method according to an embodiment of the present disclosure.

In accordance with a preferred embodiment of the present disclosure, diagnosis charging is performed for a large number of batteries having the same standard, thereby obtaining intrinsic charging profiles, and normal distribution analysis is performed for first peak positions (coordinates) of the intrinsic charging profiles obtained as described above, thereby deriving an average m and a standard deviation σ. Thereafter, a safe charging range for an x-coordinate (a voltage V in the case of FIG. 7) and a safe charging range for a y-coordinate (a first derivative dQ/dV of a charging amount with respect to a voltage in the case of FIG. 7) are set with reference to a quality management standard (set to 3 σ in the case of FIG. 7), and an area in which the safe charging range of the x-coordinate and the safe charging range of the y-coordinate overlap each other is set to a safe area (see FIG. 8).

In addition, when the first peak position (coordinates) of the charging profile of the currently-diagnosed battery is present in the safe area, the battery diagnosing unit 140 determines (diagnoses) the battery to be in a safe state, whereas, when the first peak position (coordinates) of the charging profile is present in an area (a dangerous area) beyond the safe area, the battery diagnosing unit 140 determines (diagnoses) the battery to be in a dangerous state.

Meanwhile, the information manager 150 stores and manages information as to the charged state detected by the charging state detector 110, the intrinsic charging profiles generated by the charging profile generator 130, the current charging profile, the safe area to be referenced by the battery diagnosing unit 140, etc.

As apparent from the above description, in accordance with the present disclosure, charging of a battery is charged at a diagnosis charging speed lower than a general charging speed only for a charging range requiring precise diagnosis of the battery (a diagnosis charging range) while being performed at the general charging speed for a charging range other than the diagnosis charging range. Accordingly, there are effects of greatly reducing a time taken for battery diagnosis and, as such, greatly enhancing a diagnosis speed and diagnosis efficiency.

In addition, in accordance with the present disclosure, a charging profile is analyzed only for a predetermined diagnosis charging range, and whether or not the battery is safe is determined based on a first peak of the charging profile. Accordingly, there is an effect of greatly reducing a time taken for generation and analysis of the charging profile and battery diagnosis.

In the specification (particularly, in the claims) of the present disclosure, use of the term “above” and similar referential terms may refer to both the singular and the plural. In addition, when a range is stated in the present disclosure, the statement includes the disclosure to which individual values within the range are applied (unless there is a statement to the contrary), and is the same as a statement of the individual values constituting the range in the detailed description of the disclosure.

Unless there is a statement of an explicit order or a statement to the contrary regarding steps constituting the method according to the present disclosure, the steps may be performed in any appropriate order. The present disclosure is not necessarily limited by the described order of the steps. Use of any examples or illustrative terms (for example, etc.) in the present disclosure is merely to describe the present disclosure in detail, and unless limited by the claims, the scope of the present disclosure is not limited by the examples or illustrative terms. Further, those skilled in the art will appreciate that various modifications, combinations, and changes may be made according to design conditions and factors within the scope of the appended claims or their equivalents.

Therefore, the spirit of the present disclosure should not be limited to the above-described embodiments, and the scope of the appended claims described below as well as all scopes equivalent to or equivalently changed from the claims are within the scope of the spirit of the present disclosure.

What is claimed is:

1. A battery diagnosing apparatus comprising:
a charged-state detector configured to detect a charged state of a battery;
a charging current controller configured to vary a charging current for the battery when the charged state of the battery corresponds to a predetermined diagnosis charging range; and
a battery diagnosing unit configured to analyze a charging profile generated during charging of the battery, thereby determining whether the battery is abnormal.

2. The battery diagnosing apparatus according to claim 1, further comprising:
a charging profile generator configured to generate a charging profile for the predetermined diagnosis charging range of the battery.

3. The battery diagnosing apparatus according to claim 1, wherein the charging current controller is configured to charge the battery at a diagnosis charging speed lower than a general charging speed when the charged state of the battery corresponds to the predetermined diagnosis charging range.

4. The battery diagnosing apparatus according to claim 1, wherein the predetermined diagnosis charging range is set with reference to a first peak of an intrinsic charging profile of the battery.

5. The battery diagnosing apparatus according to claim 1, wherein the battery diagnosing unit is configured to analyze whether a first peak of the charging profile is positioned in a predetermined safe area, thereby determining whether the battery is abnormal.

6. The battery diagnosing apparatus according to claim 5, wherein the predetermined safe area is set based on an average and a standard deviation of first peaks of intrinsic charging profiles for a plurality of batteries having a standard identical to a standard of the battery.

7. The battery diagnosing apparatus according to claim 1, wherein the charging profile is incremental capacity and differential voltage (IC-DV) information of the battery.

8. A battery diagnosing method comprising:
detecting, by a charged-state detector, a charged state of a battery;
varying, by a charging current controller, a charging current for the battery when the charged state of the battery corresponds to a predetermined diagnosis charging range, thereby generating a charging profile for the diagnosis charging range of the battery; and
analyzing, by a battery diagnosing unit, the generated charging profile, thereby determining whether the battery is abnormal.

9. The battery diagnosing method according to claim 8, wherein generating a charging profile comprises charging the battery at a diagnosis charging speed lower than a general charging speed when the charged state of the battery corresponds to the predetermined diagnosis charging range, thereby generating a charging profile for the diagnosis charging range of the battery.

10. The battery diagnosing method according to claim 9, wherein the diagnosis charging range is set with reference to a first peak of an intrinsic charging profile of the battery.

11. The battery diagnosing method according to claim 9, wherein determining whether the battery is abnormal comprises analyzing whether a first peak of the generated charging profile is positioned in a predetermined safe area.

12. The battery diagnosing method according to claim 11, wherein the predetermined safe area is set based on an average and a standard deviation of first peaks of intrinsic charging profiles for a plurality of batteries having a standard identical to a standard of the battery.

13. The battery diagnosing method according to claim 9, wherein the charging profile is incremental capacity and differential voltage (IC-DV) information of the battery.
